(19) United States
(12) Patent Application Publication
(10) Pub. No.: US 2026/0190520 A1
(43) Pub. Date: Jul. 2, 2026

(54) SEMICONDUCTOR DEVICE AND METHOD OF MANUFACTURING THE SAME

(71) Applicant: Taiwan Semiconductor Manufacturing Company, Ltd., Hsinchu (TW)

(72) Inventors: Yin-Kai Liao, Taipei City (TW); Jen-Cheng Liu, Hsin-Chu City (TW); Hsing-Chih Lin, Tainan City (TW); Yi-Shin Chu, Hsinchu City (TW); Hsiang-Lin Chen, Hsinchu County (TW); Sin-Yi Jiang, Hsinchu City (TW); Sung-Wen Huang Chen, Nantou County (TW); Jung-I Lin, Hsinchu City (TW)

(21) Appl. No.: 19/003,122

(22) Filed: Dec. 27, 2024

(51) Int. Cl. H10F 39/00; H10F 39/18

(52) U.S. Cl. CPC H10F 39/8033; H10F 39/014; H10F 39/184; H10F 39/807

(57) ABSTRACT

Some embodiments relate to an image-sensor integrated circuit (IC) that includes an array of avalanche photodiode (APD) elements. A first APD element of the array of APD elements includes an absorption region having a germanium semiconductor and a multiplication region including a diode of a silicon semiconductor. The absorption region is configured to generate a charge carrier in response to an incident photon. The multiplication region is configured to generate an avalanche current of charge carriers in response to the generated charge carrier drifting into the multiplication region. The first APD element further includes: a first-type-doped region for collecting charge carriers of the avalanche current, a mesh structure enclosing the absorption region, and a butted contact having a deep contact section in contact with the first-type-doped region and a mesh section connected to a corresponding portion of the mesh structure.

### BACKGROUND

Many electronic devices include integrated-circuit (IC) photon-sensitive elements to convert incident light into electric signals that are then used to generate corresponding digital data, such as, for example, images. Typical IC photon-sensitive elements, or photodetectors, may be manufactured using complementary metal-oxide-semiconductor (CMOS) technology. Notably, different applications benefit from correspondingly different types of photodetectors. Photodetectors for capturing images, for example, may function to determine the intensity of incident light at particular frequencies. Photodetectors often include photodiodes.

Photodiodes are diodes operating under a reverse bias such that when exposed to light, absorbed photons generate charge carriers propelled by the reverse bias to form a current that is generally proportional to the intensity of the light. An Avalanche photodiode (APD) is a type of photodiode that operates under a high reverse bias and is designed to respond to the absorption of incident photons by generating an avalanche breakdown current, wherein impact ionization generates additional charge carriers within the photodiode. The avalanche current provides a current gain, making an APD particularly sensitive to low light. A single-photon avalanche diode (SPAD) is a type of APD that operates at an even higher reverse bias and may be able to detect a single incident photon.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a simplified plan view of an example array of SPAD elements in accordance with some embodiments of the disclosure.

FIG. 2 illustrates a simplified plan view of an example four element array of SPAD elements in accordance with some embodiments of the disclosure.

FIG. 3 illustrates a simplified plan view of an example isolated SPAD element in accordance with some embodiments of the disclosure.

FIG. 4 illustrates a simplified example cross-sectional view of the SPAD element of FIG. 3 along a cut line of FIG. 3, in accordance with some embodiments of the disclosure.

FIGS. 5-26 illustrate simplified cross-sectional views of various example stages of fabrication of a SPAD element in accordance with some embodiments of the disclosure.

FIG. 27 illustrates a flowchart of an example method of forming a SPAD element in accordance with some embodiments of the disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “under,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees, 180 degrees, or at other orientations) and the spatially relative descriptors used herein may likewise be interpreted accordingly.

Moreover, “first,” “second,” “third,” etc. may be used herein for ease of description to distinguish between different elements of a figure or a series of figures. “first,” “second,” “third,” etc. are not intended to be descriptive of the corresponding element, but rather are merely generic identifiers. For example, “a first dielectric layer” described in connection with a first figure may not necessarily correspond to a “first dielectric layer” described in connection with some other embodiments, but rather may correspond to a “second dielectric layer” in other embodiments.

The single-photon avalanche diode (SPAD) is an avalanche photodiode (APD) configured to operate at a reverse bias beyond the breakdown voltage of the photodiode, in an operating mode known as Geiger mode. This allows a single incident photon to generate a charge carrier (e.g., an electron) that gains sufficient kinetic energy from the strong electric field to cause impact ionization and trigger a large avalanche current that allows detection of the single incident photon. Arrays of SPADs may be used in a various applications such as, for example, LiDAR (light detection and ranging) systems, other time-of-flight (ToF) systems, PET (positron emission tomography) scanning, quantum computing, and other applications that benefit from relatively precise spatial and temporal photonic information.

A SPAD typically includes an absorption region and a multiplication region. The absorption region is where an incident photon is absorbed to generate an electron-hole pair. The electric field then accelerates the electron into the multiplication region, where it can trigger a chain reaction of multiple impact ionization events that in turn triggers an avalanche current, which may lead to detection of the incident photon within picoseconds of its absorption. The avalanche current may then be quenched by a passive circuit or an active circuit to ready the SPAD to detect another photon. Quenching also helps prevent damage to the diode from the avalanche current.

Notably, different materials are better suited for absorbing photons of different wavelength ranges. While silicon (Si) is useful for absorbing photons in the visible light spectrum, germanium (Ge) is useful for absorbing photons in the infrared range. Some LiDAR systems use infrared light for projection and detection since infrared systems'eye-safety power thresholds are much higher than for visible-light systems. Some SPADs use germanium for the absorption region and silicon for the multiplication region, utilizing the particular benefits of each semiconductor.

It should be noted that while a single incident photon may be detected by a SPAD, not every single incident photon will necessarily be detected. That is because not every incident photon—even if in the appropriate wavelength range—will be absorbed and trigger an electron-hole pair formation and not every generated charge carrier will succeed in triggering an avalanche current. There are many factors that influence the efficiency of operation of a SPAD. For example, increasing the reverse bias strengthens the electric field and increases the likelihood of detection, but, significantly, also increases the dark count rate (DCR), which is the rate of false detections when no photons are incident on the device. These typically arise from thermally generated electron-hole pairs that then trigger an avalanche current. Often, varying a particular factor to increase the efficiency of photon detection has a side effect such as increasing the DCR and, similarly, often, varying a particular factor to reduce the DCR has a side effect of reducing the efficiency of photon detection.

Many IC components use silicide contacts in order to reduce contact resistance between silicon and metal and improve circuit efficiency. However, the silicidation process of forming a metal and silicon silicide deforms the silicon structure in a way that increases the dark count rate in a SPAD. Forgoing silicidation to reduce the dark count rate and using a non-silicide contact results in a higher resistance than using a silicide contact and this higher resistance results in a greater resistive-capacitive (RC) delay in the SPAD circuit, which negatively impacts SPAD performance. Using butted contacts, which correspond to connected and enlarged contacts, in conjunction with non-silicide contacts results in a lower resistance than using separate smaller contacts and, consequently, mitigates RC delays caused by the contact.

In an array of SPADs, SPADs are isolated from each other by various means to avoid photonic and electrical interference between SPADs. To avoid photon ingress from a neighboring SPADs, a metallic mesh structure that form walls between SPADs may be used. Segments of the mesh structure may be connected to certain SPAD circuit contacts of a corresponding SPAD to form butted contacts for that SPAD to provide a reduced-resistance contact.

In some embodiments of the present disclosure, an integrated circuit (IC) includes an array of avalanche photodiode (APD) elements. A first APD element of the array of APD elements includes an absorption region having a first-type semiconductor and a multiplication region including a diode of a second-type semiconductor. The absorption region is configured to generate a charge carrier in response to an incident photon. The multiplication region is configured to generate an avalanche current of charge carriers in response to the generated charge carrier drifting into the multiplication region. The first APD element further includes: a first-type-doped region for collecting charge carriers of the avalanche current, a mesh structure enclosing the absorption region, and a butted contact having a deep contact section in contact with the first-typed region and a mesh section connected to a corresponding portion of the mesh structure.

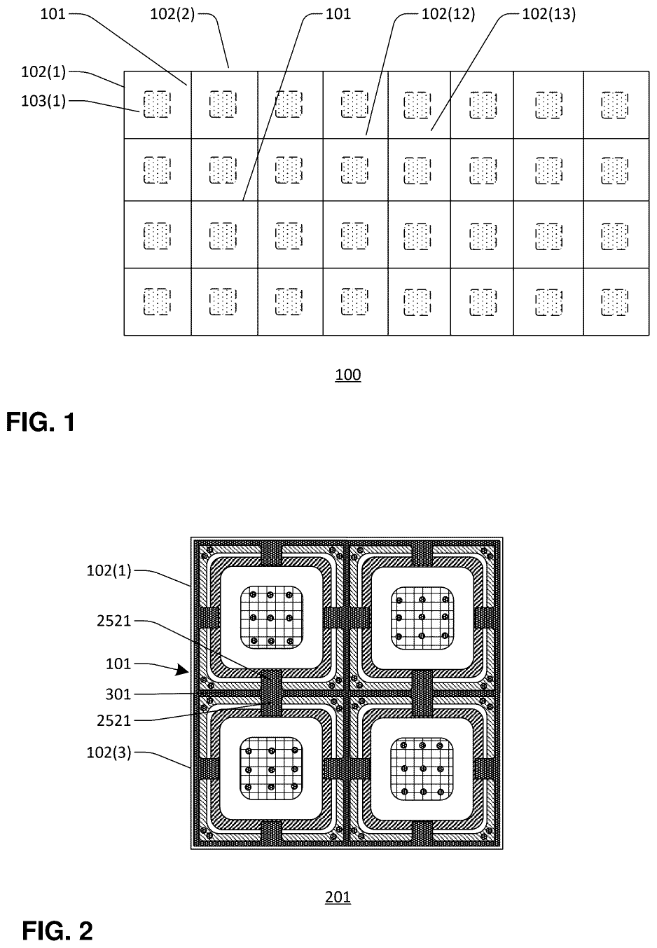

FIG. 1 illustrates a simplified plan view of an example array 100 of SPAD elements 102 in accordance with some embodiments of the disclosure. The array 100 may be a sub-array of a larger array of SPAD elements 102 such as elements 102(1), 102(2), 102(12) and 102(13). For example, the array 100, which includes 32 SPAD elements 102 may be part of a larger array of millions of SPAD elements 102. SPAD elements 102 are separated from each other by shared isolation structures 101 that include mesh structures and trench isolation structures, as described in further detail below. Each SPAD element 102 includes an absorption region 103 such as absorption region 103(1) of SPAD element 102(1). The other SPAD elements 102 are substantially identical.

FIG. 2 illustrates a simplified plan view of an example four element array 201 of SPAD elements 102 in accordance with some embodiments of the disclosure, showing select elements of the array 201. The example SPAD elements 102(1) and 102(3) may correspond to any SPAD element 102 of FIG. 1. FIG. 2 illustrates mesh structure 301 and butted contact 2521 as part of shared isolation structures 101 that separate adjoining SPAD elements 102, such as example SPAD elements 102(1) and 102(3).

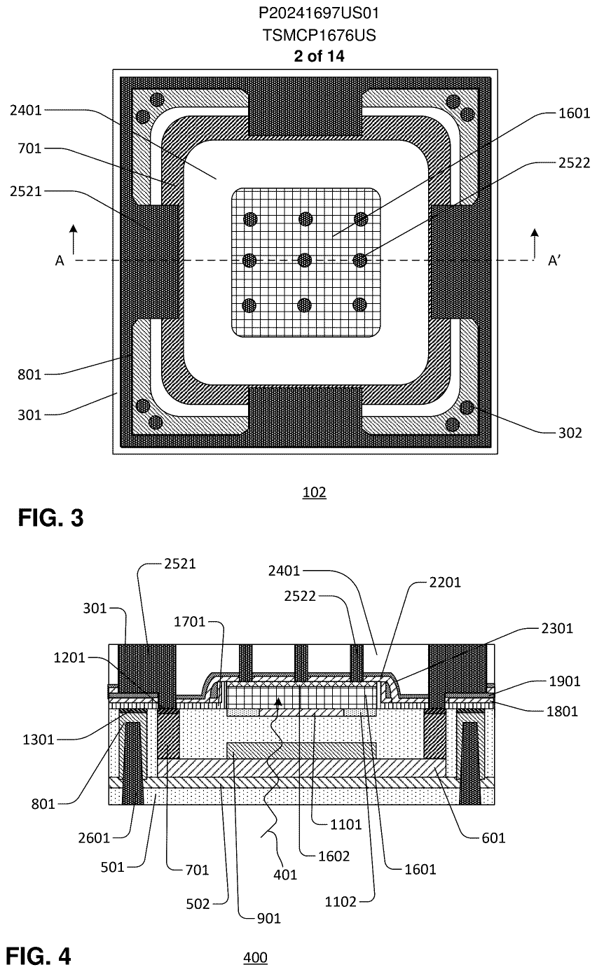

FIG. 3 illustrates a simplified plan view of select features of an example isolated SPAD element 102 in accordance with some embodiments of the disclosure, showing select elements of the SPAD element 102. The SPAD element 102 may correspond to any elements 102 of FIG. 1 or 2. The SPAD element 102 is centered around an absorption region 1601 comprising a germanium mesa structure. The absorption region 1601 is shown as a rounded square in this plan view, however it can be of any suitable geometry, including, for example, circle, square, octagon, or other polygon. The absorption region 1601 connects to an array of contacts 2522, which may be metallic vias. For simplicity, only one example contact 2522 is labeled in the figure. A contact 2522 may be referred to as a biasing contact. The SPAD element 102 includes a deep N well structure 701 that encloses the central area of the SPAD element 102 and that is connect to the butted contact 2521. The deep N well structure 701 is shown as a rounded square in the plan view, however it, like other components described throughout, can be of any suitable geometry consistent with the description. The shared isolation structures 101 include a deep P well that includes the lateral wall portion 801 shown. The lateral wall portion 801 of the deep P well connects to an array of contacts 302, which may be metallic vias. For simplicity, only one example contact 302 is labeled in the figure. The contacts 302 may be used to bias the deep P well to enhance its electrical isolation function. The SPAD element 102 also includes dielectric material 2401, which may be an intermetallic or interlayer dielectric such as silicon dioxide (SiO₂).

FIG. 4 illustrates a simplified example cross-sectional view 400 of the SPAD element 102 of FIG. 3 along cut line A-A′ of FIG. 3 in accordance with some embodiments of the disclosure. The SPAD element 102 is configured to detect a single incident photon such as example photon 401. It should be noted that the SPAD element 102 is configured to be backside illuminated for detection of photons incident from the backside or bottom (as oriented in the figure). This allows the IC comprising SPAD element 102 to be part of a 3D or compound IC where the SPAD IC is bonded at the top to a second IC, where the second IC may provide logic, memory, control, and/or other functionality for the SPAD elements 102 and the array 100 of FIG. 1. The backside of the SPAD IC may include lens elements (not shown) for enhanced photon capture.

The incident photon 401 may be absorbed by the germanium mesa structure that forms the absorption region 1601, where the absorption creates an electron-hole pair. An electric field in the absorption region 1601 propels the electron through the N channel 1101 to the multiplication region comprising P region 901 and adjoining subjacent N region 601 that form a diode. A strong electric field in the multiplication region accelerates the generated electron so that it may trigger an avalanche current through a chain reaction of impact ionizations. Electrons are collected by the N region 601 and transported via deep N well 701 and N+ region 1201 to butted contact 2521 and to a detection circuit (not shown). The avalanche current is then quenched, as described above, to prevent damage to the circuit and to reset the SPAD element 102 for detecting a next incident photon. The N+ region 1201 reduces contact resistance between the butted contact 2521 and the deep N well 701. As explained above, the N+ region 1201 does not undergo silicidation so as to avoid increasing the DCR of the SPAD element 102. The N+ region 1201 corresponds to the deep N well 701 and has substantially the same plan layout as the deep N well 701 (see, e.g., FIG. 3).

Referring to FIGS. 3 and 4, each butted contact 2521 extends along a significant segment of the deep N well 701 and corresponding N+ region 1201 that it overlays. This allows for more contact area between the butted contact 2521 and the N+ region 1201 than would be available if using interspaced contact vias in the same area. As noted, the increased contact area helps reduce contact resistance and, consequently, reduce RC delay in the SPAD element 102. The butted contact 2521 may extend along more than a quarter of the perimeter of the deep N well 701 and corresponding N+ region 1201. In some implementations, the butted contact 2521 may extend along more than half of the perimeter of the deep N well 701 and corresponding N+ region 1201.

Aside from the above described elements, the SPAD element 102 includes various other elements described below. Elements of the SPAD element 102 are formed in and on epitaxial silicon layer 501. Note that in alternative embodiments, substrate silicon, or a combination of substrate and epitaxial silicon may be used instead. Epitaxial silicon layer 501 may be intrinsic silicon or may be lightly p doped. Electrical isolation is provided by a deep P well comprising a planar portion of p-type isolation layer 502 subjacent to the N region 601 of the multiplication region and a lateral wall portion 801 enclosing the multiplication region. The p-type lateral wall portion 801 is topped with a P+ region 1301, which reduces resistance with the contacts 302 shown in FIG. 3. The P+ region 1301 corresponds to the lateral wall portion 801 and has substantially the same plan layout as the lateral wall portion 801 (see, e.g., FIG. 3). The lateral wall portion 801 is shown as substantially rectangular, but can be of any suitable geometry that suitably encloses the multiplication region. A backside deep trench isolation (BDTI) structure 2601 provides photonic isolation from adjacent SPAD elements or other components by blocking incident photons from outside the SPAD element 102. The BDTI structure 2601, which may be tungsten or other suitable conductor, is underneath and partially inside the lateral wall portion 801. The BDTI structure 2601 substantially corresponds to the mesh structure 301 and serves a similar function. In some embodiments, the BDTI structure 2601 is a continuous ring shape complementary to a continuous ring shape of lateral wall portion 801.

The N channel 1101, which supports transfer of electrons generated in the absorption region 1601 to the silicon region below and to the reverse-biased diode of P region 901 and N region 601, is laterally enclosed by P region 1102. The absorption region 1601 is a germanium mesa structure encapsulated or capped by a p-type doped silicon cap section 1602 and an intrinsic silicon cap 1701 including a sidewall section and a horizontal section. The capping prevents damage to the germanium absorption region 1601 from the phosphoric acid (H₃PO₄) used in etching and/or cleaning steps of the fabrication of the SPAD element 102. The top of the epitaxial silicon layer 501 is overlain with a horizontal portion of the silicon cap 1701. The silicon cap 1701, including its sidewall section, and the cap section 1602, are overlain with a layer of spacer silicon dioxide (SiO₂) 1801, a layer of spacer silicon nitride (Si₃N₄) 1901, a layer of resist protection oxide (RPO) 2201, a layer of silicon nitride 2301, and dielectric 2401.

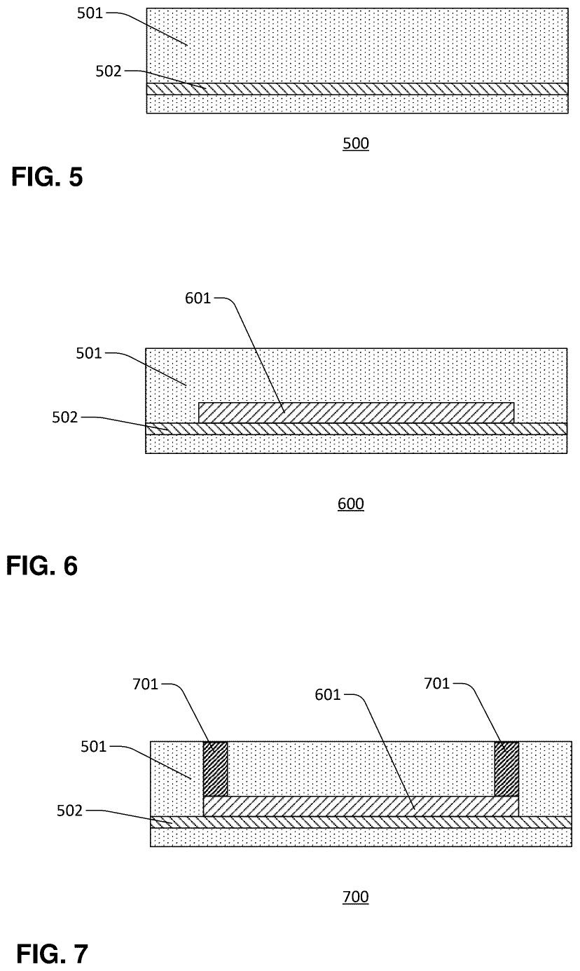

FIGS. 5-26 illustrate simplified cross-sectional views of some stages of an example fabrication process of an SPAD element 102 in accordance with some embodiments of the disclosure. Although FIGS. 5-26 are described as a series of acts, it will be appreciated that these acts are not limiting in that the order of the acts can be altered in other embodiments, and the methods disclosed are also applicable to other structures. In some embodiments, alternative steps may be performed instead of the steps described. In some embodiments, some acts that are illustrated and/or described may be omitted in whole or in part. In some embodiment, additional acts that are not described herein may also be performed as part of the manufacturing process.

FIG. 5 illustrates a simplified cross-sectional view of a portion 500 of a wafer comprising a silicon layer 501. The portion 500 corresponds to an example SPAD element 102. The silicon layer 501 may be epitaxial silicon grown on a silicon substrate (not shown) or grown on an insulator substrate (not shown). The silicon substate may be intrinsic silicon. In some embodiments the silicon substrate may be lightly p-type doped. The epitaxial silicon layer 501 may be intrinsic silicon. In some embodiments the epitaxial silicon layer 501 may be lightly p-type doped. P-type doping may be done with, for example, boron (B), aluminum (Al), indium (In), gallium (Ga), or any other suitable acceptor material. The silicon layer 501 may be grown using, for example, chemical vapor deposition (CVD) or any other suitable epitaxy method.

The p-type isolation layer 502 is fabricated using ion implantation of p-type dopants such as, for example, boron or aluminum. By controlling the energy of the ion implantation beam, a desired depth profile may be achieved. The p-type isolation layer 502 forms the planar portion of the deep P well isolation structure for providing electrical isolation to the multiplication region of the SPAD element 102.

FIG. 6 illustrates a simplified cross-sectional view of a portion 600, corresponding to the portion 500 of FIG. 5 after the formation of the N region 601 of the PN diode of the multiplication region of the SPAD element 102. The N region 601 is formed using ion implantation of n-type dopants such as, for example, phosphorous, arsenic, or other suitable donor material.

FIG. 7 illustrates a simplified cross-sectional view of a portion 700, corresponding to the portion 600 of FIG. 6 after the formation of the deep N well structure 701 of the multiplication region of the SPAD element 102. The deep N well structure 701 is formed using ion implantation of n-type dopants such as, for example, phosphorous, arsenic, or other suitable donor material.

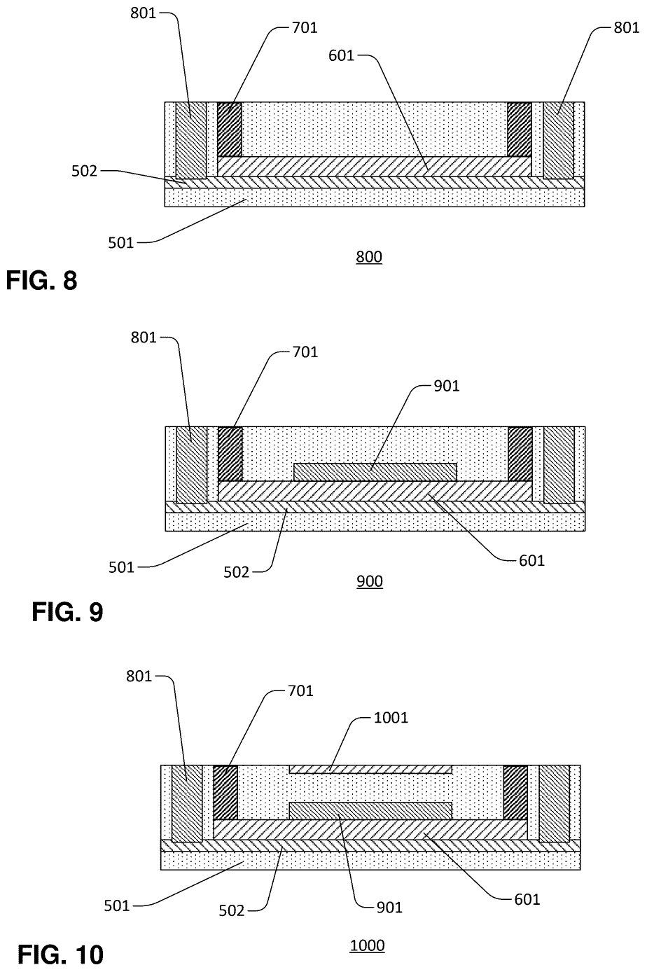

FIG. 8 illustrates a simplified cross-sectional view of a portion 800, corresponding to the portion 700 of FIG. 7 after the formation of the lateral wall portion 801 of the deep P well isolation structure for providing electrical isolation to the multiplication region of the SPAD element 102. The lateral wall portion 801 of the deep P well isolation structure is formed using ion implantation of p-type dopants such as, for example, boron, aluminum, or other suitable acceptor material.

FIG. 9 illustrates a simplified cross-sectional view of a portion 900, corresponding to the portion 800 of FIG. 8 after the formation of the P region 901 of the PN diode of the multiplication region of the SPAD element 102. The P region 901 is formed using ion implantation of p-type dopants such as, for example, boron, aluminum, or other suitable acceptor material. The P region 901 may be substantially square or of similar geometry and may correspond to the footprint of the absorption region 1601.

FIG. 10 illustrates a simplified cross-sectional view of a portion 1000, corresponding to the portion 900 of FIG. 9 after the formation of the N region 1001 that will be the basis for the N channel 1101. The N region 1001 may be substantially square or of similar geometry and may correspond to the footprint of the absorption region 1601. The N region 1001 may be formed using ion implantation of n-type dopants such as, for example, phosphorous, arsenic, or other suitable donor material. Alternatively, the N region 1001 may be formed using diffusion through an opening defined by a mask (not shown) overlaying the silicon layer 501.

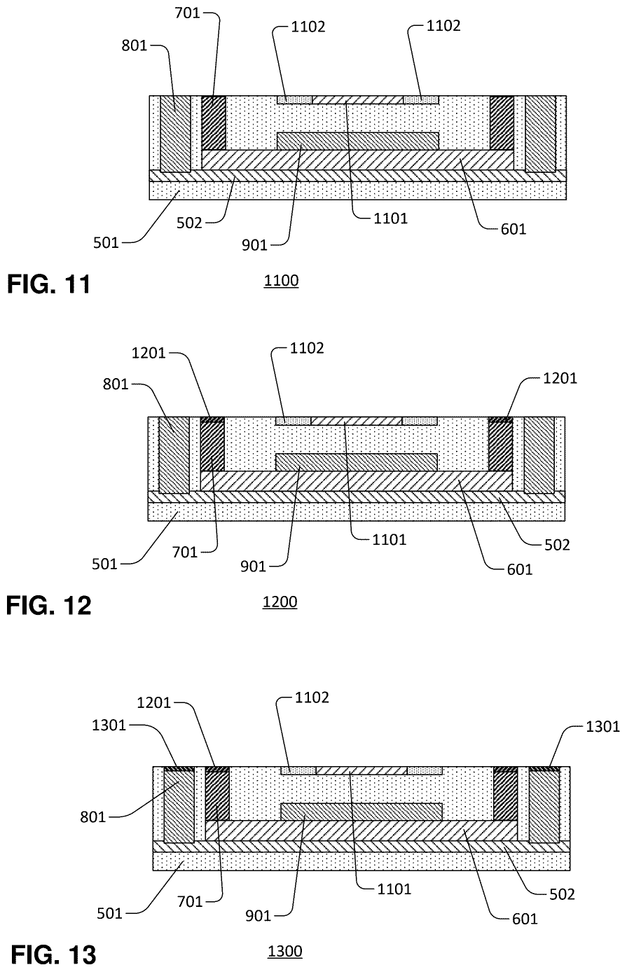

FIG. 11 illustrates a simplified cross-sectional view of a portion 1100, corresponding to the portion 1000 of FIG. 10 after the formation of P region 1102 surrounding and defining the N channel 1101 from the N region 1001 of portion 1000. The P region 1102 may have a square, ring, or similar geometry in a plan view (not shown). The P region 1102 may be formed using ion implantation of p-type dopants such as, for example, boron, aluminum, or other suitable acceptor material. Alternatively, the P region 1102 may be formed using diffusion through an opening defined by a mask (not shown) overlaying the silicon layer 501.

FIG. 12 illustrates a simplified cross-sectional view of a portion 1200, corresponding to the portion 1100 of FIG. 11 after the formation of N+ region 1201. The N+ region 1201 corresponds to the top of the deep N well region 701. The N+ region 1201 may be formed using ion implantation of n-type dopants such as, for example, phosphorous, arsenic, or other suitable donor material. Alternatively, the N+ region 1201 may be formed using diffusion through an opening defined by a mask (not shown) overlaying the silicon layer 501.

FIG. 13 illustrates a simplified cross-sectional view of a portion 1300, corresponding to the portion 1200 of FIG. 12 after the formation of P+ region 1301. The P+ region 1301 corresponds to the top of the lateral wall portion 801 of the deep P well isolation structure surrounding the multiplication region of the SPAD element 102. The P+ region 1301 may be formed using ion implantation of p-type dopants such as, for example, boron, aluminum, or other suitable acceptor material. Alternatively, the P+ region 1301 may be formed using diffusion through an opening defined by a mask (not shown) overlaying the silicon layer 501.

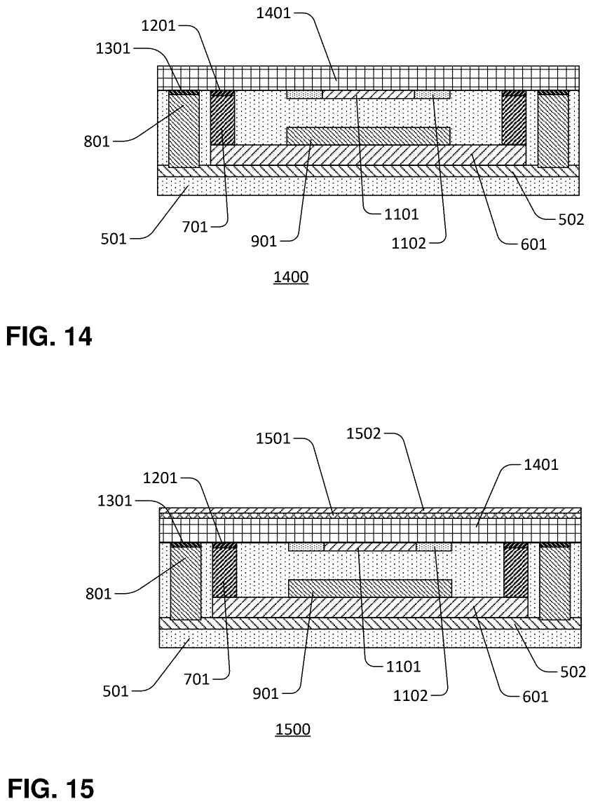

FIG. 14 illustrates a simplified cross-sectional view of a portion 1400, corresponding to the portion 1300 of FIG. 13 after the formation of a germanium layer 1401. The germanium may be intrinsic or may be p-typed doped with, for example, boron, which may help a reduce dark count rate for the absorption region. The germanium layer 1401 may be formed by a deposition process, such as, for example, chemical vapor deposition (CVD), physical vapor deposition (PVD), sputtering, or the like.

FIG. 15 illustrates a simplified cross-sectional view of a portion 1500, corresponding to the portion 1400 of FIG. 14 after the formation of a p-type doped silicon layer 1501 overlaying the germanium layer 1401 and an oxide layer 1502 overlaying the silicon layer 1501. The silicon layer 1501 may be initially formed by a deposition process, such as, for example, chemical vapor deposition (CVD), physical vapor deposition (PVD), sputtering, or the like. The silicon layer 1501 may be doped with boron, aluminum, or other suitable acceptor material. The silicon layer 1501 may be doped using, for example, in-situ doping during deposition, post-deposition diffusion, ion implantation, and/or any other suitable doping method. The oxide layer 1502 may comprise silicon dioxide and may be formed by a deposition process, such as, for example, chemical vapor deposition (CVD).

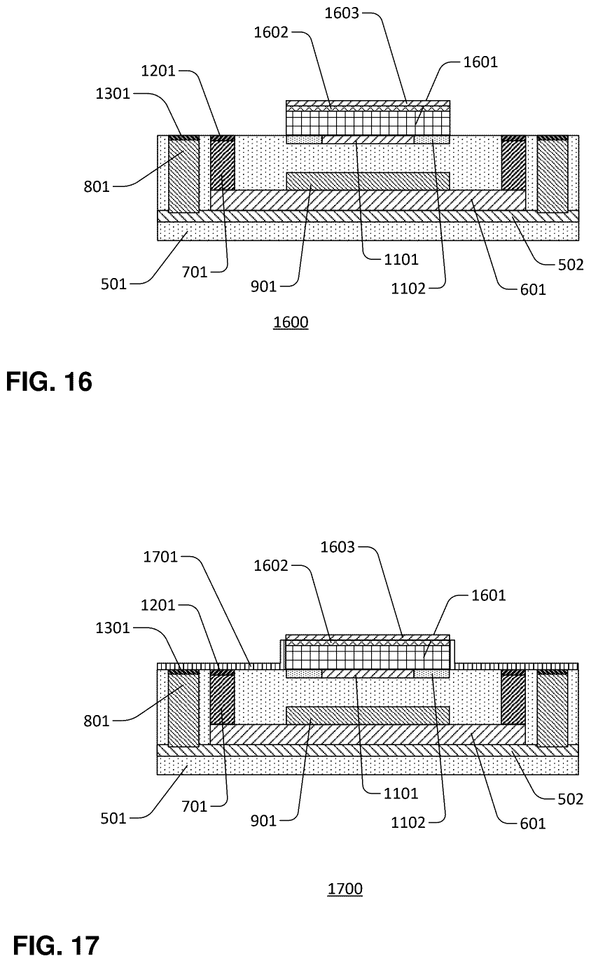

FIG. 16 illustrates a simplified cross-sectional view of a portion 1600, corresponding to the portion 1500 of FIG. 15 after the formation of the germanium mesa structure, corresponding to absorption region 1601 with p-type doped silicon cap section 1602 and oxide top section 1603. The mesa structure corresponding to the absorption region 1601 with cap section 1602 and oxide top section 1603 may be formed by etching layers 1401, 1501, and 1502 of portion 1500 using a patterning layer (not shown). The patterning layer may be a hardened part of a photoresist mask developed using a photolithography process. The patterning layer may alternatively be a hardmask layer formed using photolithographically developed photoresist (not shown) and etching. The etching may be dry etching with, for example, a dry etchant such as, for example, a fluorine-containing gas such as CF₄, a gaseous mixture of xenon and fluoride (e.g., XeF₆), sulfur and fluoride (e.g., SF₆), or some other suitable mixture.

FIG. 17 illustrates a simplified cross-sectional view of a portion 1700, corresponding to the portion 1600 of FIG. 16 after the formation of intrinsic silicon cap 1701, including intrinsic silicon sidewalls for the germanium mesa structure corresponding to the absorption region 1601. The intrinsic silicon cap 1701 may be formed by a deposition process, such as, for example, chemical vapor deposition (CVD), with the assistance of the oxide top section 1603.

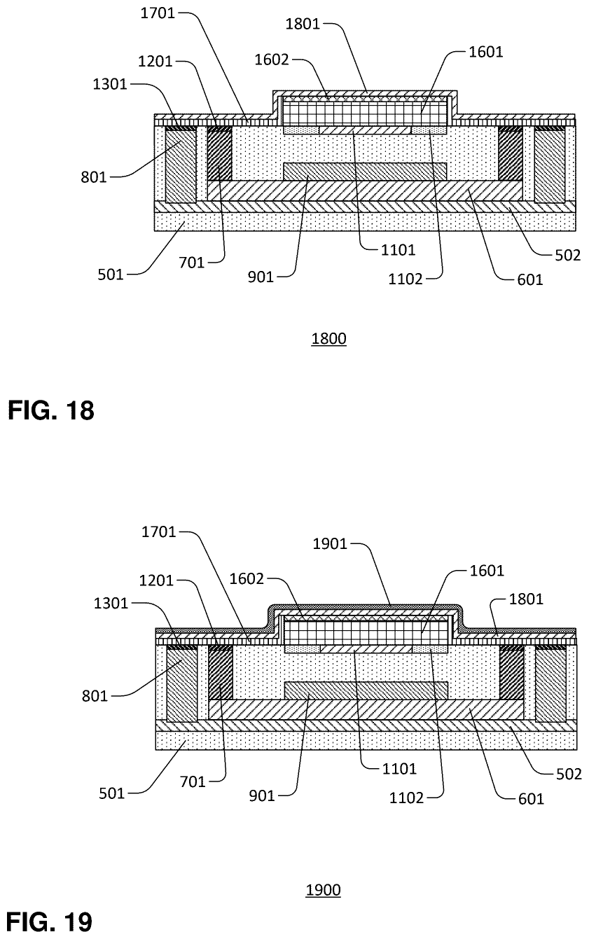

FIG. 18 illustrates a simplified cross-sectional view of a portion 1800, corresponding to the portion 1700 of FIG. 17 after the removal of the oxide top section 1603 and the formation of a spacer oxide layer 1801 overlaying the silicon cap 1701 and the cap section 1602. The spacer oxide layer 1801 may comprise silicon dioxide and may be formed by a deposition process, such as, for example, chemical vapor deposition (CVD).

FIG. 19 illustrates a simplified cross-sectional view of a portion 1900, corresponding to the portion 1800 of FIG. 18 after the formation of a spacer nitride layer 1901 overlaying the spacer oxide layer 1801. The spacer nitride layer 1901 may comprise silicon nitride and may be formed by a deposition process, such as, for example, chemical vapor deposition (CVD). The spacer oxide layer 1801 and spacer nitride layer 1901 may help define the opening for the butted contact 2521, as described below.

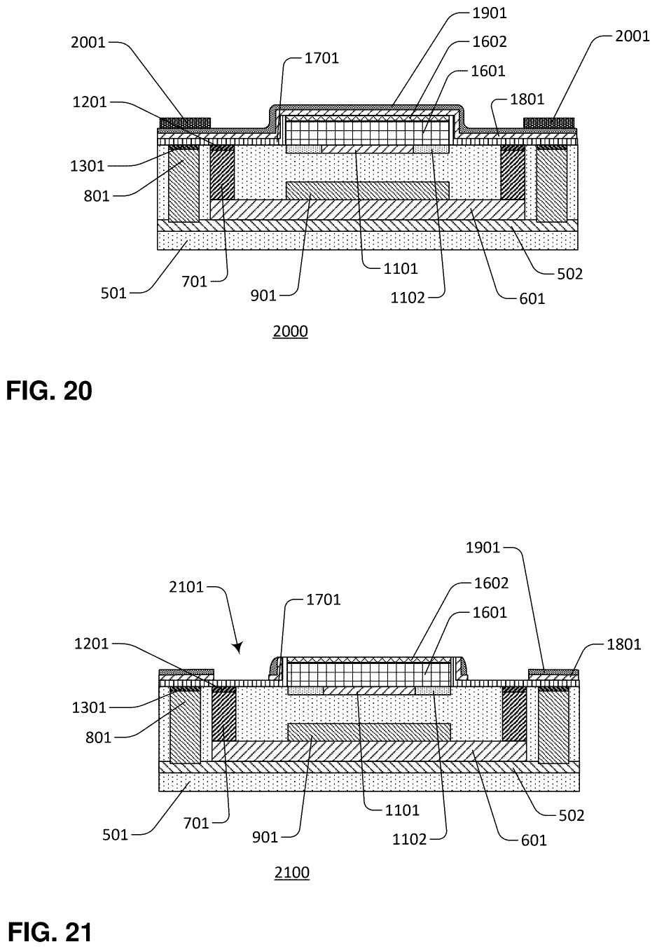

FIG. 20 illustrates a simplified cross-sectional view of a portion 2000, corresponding to the portion 1900 of FIG. 19 after the formation of etching pattern 2001. The etching pattern 2001 may by a developed photoresist. An undeveloped photoresist layer may be deposited via a spin coating process, a deposition process, or the like. A photolithographic process may then be executed wherein the undeveloped photoresist is selectively exposed to electromagnetic radiation based on a photo mask, whereupon the electromagnetic radiation modifies a solubility of exposed regions of the photoresist to define soluble regions. The soluble regions are then removed (for example, by washing) to leave the etching pattern 2001.

FIG. 21 illustrates a simplified cross-sectional view of a portion 2100, corresponding to the portion 2000 of FIG. 20 after the formation of openings 2101 by etching in accordance with the etching pattern 2001 of FIG. 20.

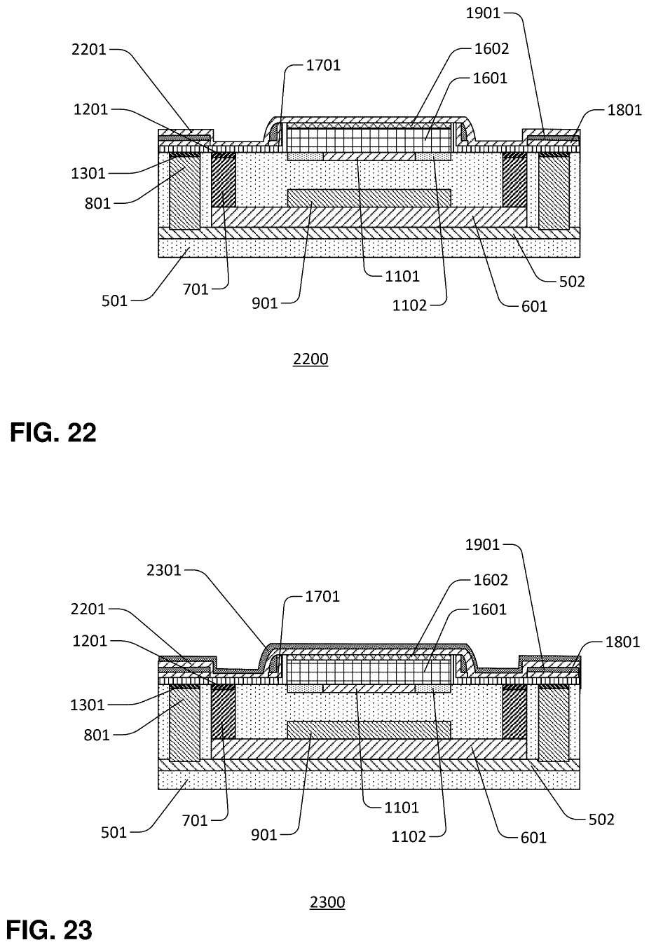

FIG. 22 illustrates a simplified cross-sectional view of a portion 2200, corresponding to the portion 2100 of FIG. 21 after the formation of resist protection oxide (RPO) layer 2201 overlaying the SPAD element 102. The RPO layer 2201 may comprise silicon dioxide and may be formed by a deposition process, such as, for example, chemical vapor deposition (CVD).

FIG. 23 illustrates a simplified cross-sectional view of a portion 2300, corresponding to the portion 2200 of FIG. 22 after the formation of a nitride layer 2301 overlaying the RPO layer 2201. The nitride layer 2301 may comprise silicon nitride and may be formed by a deposition process, such as, for example, chemical vapor deposition (CVD).

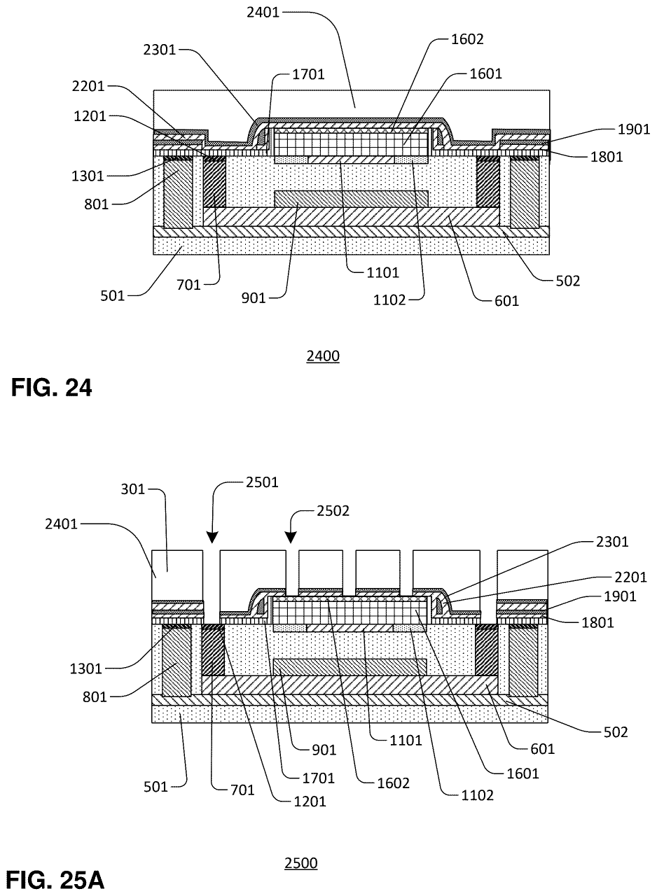

FIG. 24 illustrates a simplified cross-sectional view of a portion 2400, corresponding to the portion 2300 of FIG. 23 after the formation of dielectric layer 2401. The dielectric layer may comprise silicon dioxide and may be formed by a deposition process, such as, for example, chemical vapor deposition (CVD).

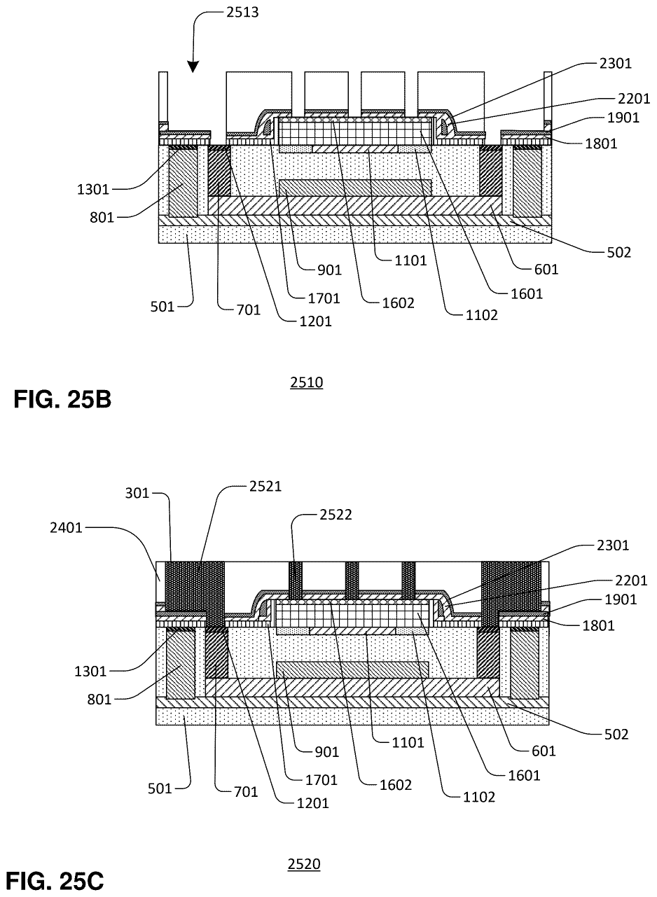

FIG. 25A illustrates a simplified cross-sectional view of a portion 2500, corresponding to the portion 2400 of FIG. 24 after etching, in accordance with corresponding etching patterns, of via holes 2501 and 2502, which go down to doped silicon features such as N+ region 1201 and p-type doped silicon cap section 1602. The etching may be performed using, for example, dry etching techniques. The etching patterns may be defined by corresponding patterning layers (not shown) as described elsewhere herein.

FIG. 25B illustrates a simplified cross-sectional view of a portion 2510, corresponding to the portion 2500 of FIG. 25A after further etching of a trench 2513 down to the spacer silicon nitride layer 1901 defining the layout of the butted contacts 2521 and the mesh structure 301. The etching patterns may be defined by corresponding patterning layers (not shown) as described elsewhere herein.

FIG. 25C illustrates a simplified cross-sectional view of a portion 2520, corresponding to the portion 2510 of FIG. 25B after the formation of absorption contacts 2522, butted contacts 2521, and the mesh structure 301 by filling of the above-described via holes and trenches with a conductor such as tungsten and performing a planarization process including, for example, a chemical mechanical polish (CMP) and/or some other suitable planarization process. Notably, the N+ region 1201 is not subjected to silicidation.

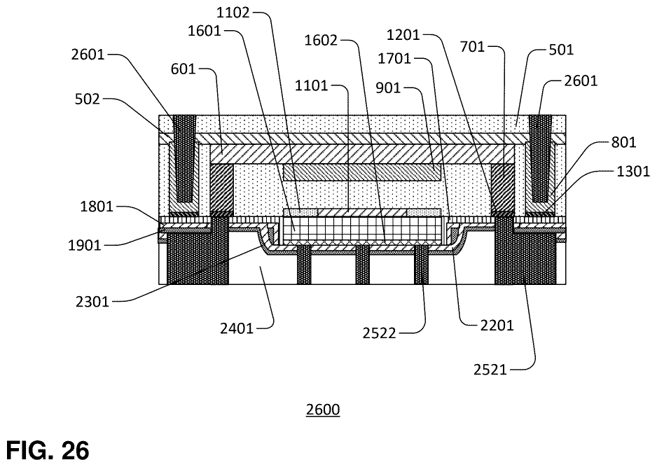

FIG. 26 illustrates a simplified cross-sectional view of a portion 2600, corresponding to the portion 2520 of FIG. 25C after turning over and the formation of the backside deep trench isolation (BDTI) structure 2601 on the backside of the wafer of the SPAD element 102. The BDTI structure 2601 may be formed by first etching a trench and then filling the trench with a conductor such as tungsten. The etching pattern may be defined by a corresponding patterning layer (not shown) as described elsewhere herein.

After the above-described wafer processing is completed, the wafer may be singulated into individual die which correspond to individual ICs.

Various doping concentrations have been described herein. Namely, light (e.g., P−), moderate (e.g., N or P), and enhanced (e.g., N+ or P+). Light doping may refer to a dopant concentration of between approximately 10¹⁴ and 10¹⁵ atoms per cubic centimeter (10¹⁴/cm³ 10¹⁵/cm³), between approximately 10¹⁴/cm³ and 10¹⁶/cm³, or other similar values. Moderate doping may refer to a dopant concentration of between approximately 10¹⁵ and 10¹⁶ atoms per cubic centimeter (10¹⁵/cm³-10¹⁶/cm³), between approximately 10¹⁵/cm³ and 10¹⁷/cm³, or other similar values. Enhanced doping may refer to a dopant concentration of between approximately 10¹⁶ and 10²⁰ atoms per cubic centimeter (10¹⁶/cm³-10²⁰/cm³).

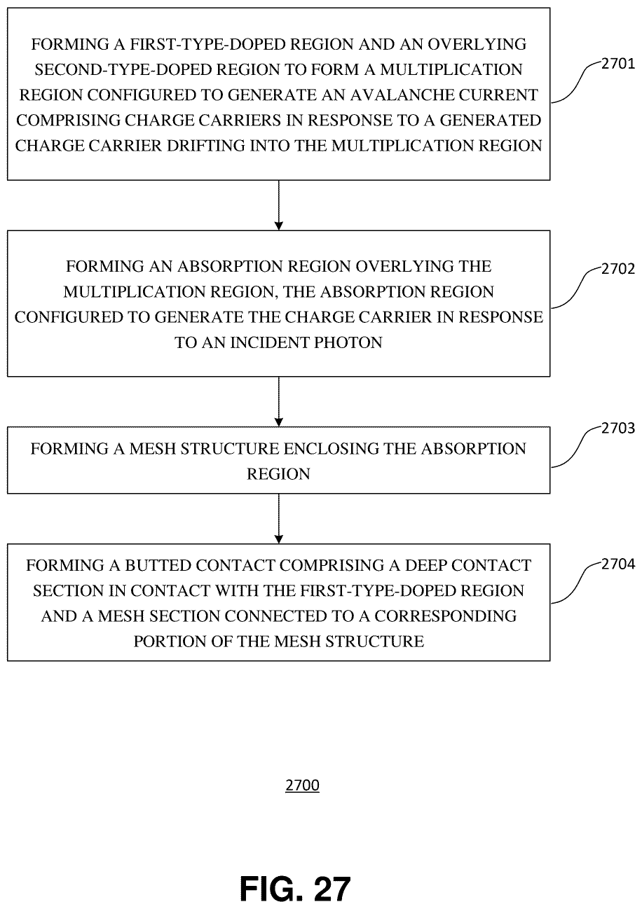

FIG. 27 is a flowchart illustrating a method 2700 of forming an SPAD element 102 in accordance with some embodiments of the disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included. Acts can correspond, for example, to the structure previously illustrated in FIGS. 5-26 in some embodiments.

At act 2701, a first-type-doped region and an overlying second-type-doped region are formed to form a multiplication region configured to generate an avalanche current comprising charge carriers in response to a generated charge carrier drifting into the multiplication region. FIGS. 6-9 illustrate cross-sectional views of some embodiments corresponding to act 2701.

At act 2702, an absorption region overlying the multiplication region is formed, the absorption region configured to generate the charge carrier in response to an incident photon. FIG. 14-16 illustrate cross-sectional views of some embodiments corresponding to act 2702.

At act 2703, a mesh structure enclosing the absorption region is formed. FIG. 25 illustrates a cross-sectional view of an embodiment corresponding to act 2703.

At act 2704, a butted contact is formed, the butted contact comprising a deep contact section in contact with the first-type-doped region and a mesh section connected to a corresponding portion of the mesh structure. FIG. 25 illustrates a cross-sectional view of an embodiment corresponding to act 2704.

Note that multiple subsequent steps (e.g., forming metallization layers and other back end of line (BEOL) steps) may be performed to produce a usable working IC device. Note that while exemplary embodiments have been described wherein the absorption semiconductor is germanium and the multiplication semiconductor is silicon, alternative embodiments may use semiconductors other than those described. For example, in some alternative implementations, silicon or indium gallium arsenide (InGaAs) may be used as the absorption semiconductor; in some alternative implementations, germanium or InGaAs may be used as the multiplication semiconductor. Similarly, semiconductors other than silicon may be used for the substrate and epitaxial layers described.

Some embodiments relate to an integrated circuit (IC) including an array of avalanche photodiode (APD) elements. A first APD element of the array of APD elements includes: an absorption region comprising an absorption semiconductor, the absorption region configured to generate a charge carrier in response to an incident photon, a multiplication region including a diode of a multiplication semiconductor, the multiplication region configured to generate an avalanche current having charge carriers in response to the generated charge carrier drifting into the multiplication region, a first-type-doped region for collecting charge carriers of the avalanche current, a mesh structure enclosing the absorption region, and a butted contact comprising a deep contact section in contact with the first-type-doped region and a mesh section connected to a corresponding portion of the mesh structure.

Some embodiments relate to a single photon avalanche diode (SPAD) including: an absorption region having an absorption semiconductor, the absorption region configured to generate a charge carrier in response to an incident photon, a multiplication region having a diode of a multiplication semiconductor, the multiplication region configured to generate an avalanche current including charge carriers in response to the generated charge carrier drifting into the multiplication region, a first-type-doped region for collecting charge carriers of the avalanche current, a conductive mesh structure surrounding the absorption region, and a butted contact comprising a via portion extending to a contact portion of the first-type-doped region and a section elevated body portion extending laterally from the via portion to the conductive mesh structure.

Some embodiments relate to a method for forming an integrated circuit device. The method includes: forming a first-type-doped region and an overlying second-type-doped region to form a multiplication region configured to generate an avalanche current comprising charge carriers in response to a generated charge carrier drifting into the multiplication region, forming an absorption region overlying the multiplication region, the absorption region configured to generate the charge carrier in response to an incident photon, forming a mesh structure enclosing the absorption region, and forming a butted contact comprising a deep contact section in contact with the first-type-doped region and a mesh section connected to a corresponding portion of the mesh structure.

It will be appreciated that in this written description, as well as in the claims below, the terms “first,” “second,” “second,” “third,” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) comprising an array of avalanche photodiode (APD) elements, wherein:
a first APD element of the array of APD elements comprises:
an absorption region comprising an absorption semiconductor, the absorption region configured to generate a charge carrier in response to an incident photon;
a multiplication region comprising a diode of a multiplication semiconductor, the multiplication region configured to generate an avalanche current comprising charge carriers in response to the generated charge carrier drifting into the multiplication region;
a first-type-doped region for collecting charge carriers of the avalanche current;
a mesh structure enclosing the absorption region; and
a butted contact comprising a deep contact section in contact with the first-type-doped region and a mesh section connected to a corresponding portion of the mesh structure.

2. The IC of claim 1, wherein the APD is a single photon avalanche diode (SPAD) configured to operate in a Geiger mode.

3. The IC of claim 1, wherein:
the absorption semiconductor is germanium; and
the multiplication semiconductor is silicon.

4. The IC of claim 3, wherein the germanium is p-type doped germanium.

5. The IC of claim 3, wherein the absorption region is a mesa structure capped by a silicon cap.

6. The IC of claim 5, wherein the silicon cap comprises a p-type doped silicon top and intrinsic silicon sidewalls.

7. The IC of claim 1, wherein:
the diode of the multiplication region comprises a p-type region overlaying an adjoining an n-type region, the two regions forming a P-N junction;
the n-type region is conductively connected to the deep contact section of the butted contact;
the absorption region is conductively connected to a biasing contact; and
the IC is configured to respectively bias the butted contact and the biasing contact so as to have a reverse bias across the P-N junction and generate an electric field sufficient to accelerate the generated charge carrier to generate the avalanche current.

8. The IC of claim 7, wherein:
a breakdown voltage characterizes the diode of the multiplication region; and
the reverse bias is greater than the breakdown voltage.

9. The IC of claim 1, wherein the butted contact comprises tungsten (W).

10. The IC of claim 1, wherein the first APD element further comprises a deep p-type well enclosing the multiplication region, the deep p-type well comprising a planar portion subjacent to the multiplication region and a lateral wall portion enclosing the multiplication region.

11. The IC of claim 10, wherein:
the butted contact overlays a corresponding segment of the lateral wall portion of the deep p-type well; and
the butted contact is separated by at least a silicon nitride layer from the corresponding segment of the lateral wall portion of the deep p-type well.

12. The IC of claim 10, wherein:
the first APD element further comprises a backside deep trench isolation (BDTI) structure underneath and at-least-partially inside the lateral wall portion of the deep p-type well; and
the BDTI structure comprises a metal.

13. The IC of claim 1, wherein the butted contact includes the corresponding portion of the mesh structure.

14. The IC of claim 1, wherein:
the array further comprises a second APD element adjoining the first APD element;
the second APD element comprises:
an absorption region comprising the absorption semiconductor, the absorption region configured to generate a charge carrier in response to an incident photon;
a multiplication region comprising a diode of the multiplication semiconductor, the multiplication region configured to generate an avalanche current comprising charge carriers in response to the generated charge carrier drifting into the multiplication region;
a first-type-doped region for collecting charge carriers of the avalanche current;
a mesh structure enclosing the absorption region; and
a butted contact comprising a deep contact section in contact with the first-type-doped region and a mesh section connected to a corresponding portion of the mesh structure; and
the first APD element and the second APD element share some intervening features such that a portion of the mesh structure of the first APD is also a portion of the mesh structure of the second APD.

15. The IC of claim 1, wherein:
the first APD has four sides in a planar view; and
the first APD comprises four butted contacts, each butted contact on a corresponding one of the four sides.

16. A single photon avalanche diode (SPAD) comprising:
an absorption region comprising an absorption semiconductor, the absorption region configured to generate a charge carrier in response to an incident photon;
a multiplication region comprising a diode of a multiplication semiconductor, the multiplication region configured to generate an avalanche current comprising charge carriers in response to the generated charge carrier drifting into the multiplication region;
a first-type-doped region for collecting charge carriers of the avalanche current;
a conductive mesh structure surrounding the absorption region; and
a butted contact comprising a via portion extending to a contact portion of the first-type-doped region and an elevated body portion extending laterally from the via portion to the conductive mesh structure.

17. A method for forming an integrated circuit device, the method comprising:
forming a first-type-doped region and an overlying second-type-doped region to form a multiplication region configured to generate an avalanche current comprising charge carriers in response to a generated charge carrier drifting into the multiplication region;
forming an absorption region overlying the multiplication region, the absorption region configured to generate the charge carrier in response to an incident photon;
forming a mesh structure enclosing the absorption region; and
forming a butted contact comprising a deep contact section in contact with the first-type-doped region and a mesh section connected to a corresponding portion of the mesh structure.

18. The method of claim 17, wherein:
the multiplication region comprises silicon; and
the absorption region comprises germanium.

19. The method of claim 17, further comprising forming a deep p-type well enclosing the multiplication region, the deep p-type well comprising a planar portion subjacent to the multiplication region and a lateral wall portion enclosing the multiplication region.

20. The method of claim 19, further comprising forming a backside deep trench isolation (BDTI) structure underneath and at-least-partially inside the lateral wall portion of the deep p-type well, wherein the BDTI structure comprises a metal.
